(19) United States
(12) Patent Application Publication
(10) Pub. No.: US 2025/0253821 A1
(43) Pub. Date: Aug. 7, 2025

(54) EMI FILTERING CIRCUIT FOR EV/HEV BATTERY CHARGERS

(71) Applicant: META SYSTEM S.P.A., REGGIO EMILIA (RE) (IT)

(72) Inventor: Cesare LASAGNI, REGGIO EMILIA (RE) (IT)

(21) Appl. No.: 18/856,316

(22) PCT Filed: Apr. 13, 2023
(86) PCT No.: PCT/IB2023/053794

§ 371 Date: Oct. 11, 2024

(30) Foreign Application Priority Data
Apr. 14, 2022 (IT) 102022000007544

(51) Int. Cl. H03H 7/01; H01F 27/24; H01F 27/28; H01F 27/40

(52) U.S. Cl. CPC H03H 7/0115; H01F 27/24; H01F 27/28; H01F 27/40

(57) ABSTRACT

An EMI filtering circuit (1) for battery chargers of EV or HEV comprising: a plurality of filters (2a, 2b) for electro-magnetic disturbances connected in cascade to each other and provided with at least one coil (2a) comprising one ferromagnetic core (3) and at least one winding (4a, 4b) provided with one input end (6) and with one output end (7): a plurality of line capacitors (2b); one printed circuit board, PCB, (8) adapted to support the capacitors (2b) and connect them to each other; a plurality of connecting elements (10) adapted to electrically connect the coils (2a) to the PCB (8); wherein each of the output ends (7) of each coil (2a), except for the last one, is directly connected to a respective input end (6) of the next coil (2a) and is associated together with the respective input end (6) to a same connecting element (10).

### TECHNICAL FIELD

The present invention relates to a filtering circuit for battery chargers of electric or hybrid vehicles.

### BACKGROUND ART

As is well known, electric vehicles use for propulsion the conversion of part of the chemical energy stored in one or more batteries into electrical energy and the subsequent transfer of the latter to the motorized unit.

For the purpose of enabling periodic charging of batteries, electric and hybrid vehicles are provided with special battery chargers (so-called “on-board chargers”, OBCs), which can be connected at input to an AC power supply line and at output to the vehicle battery, which chargers are adapted to convert the AC current at input into a corresponding, predefined DC current to be sent at outlet to the battery for storage.

In this regard, it should be mentioned that the above conversions are carried out, in the battery charger, by a power unit operating at high voltages and because of this, they may generate electromagnetic disturbances that are likely to be propagated to the power supply line.

In order to overcome this problem, battery chargers are provided with filtering circuits intended to filter such electromagnetic disturbances coming from downstream.

An example of known filtering circuits is given in FIG. 1.

As can be seen, known filtering circuits C comprise one or more filters F from electromagnetic disturbances (e.g., of the EMI filter type) comprising a coil B and a plurality of capacitors CND both mounted on a printed circuit board S. Specifically, each coil B comprises a ferromagnetic core N, e.g., toroidal (as shown in FIG. 1 and FIG. 2) or oval in shape, and four windings V each of which is wound around a respective winding portion P of the ferromagnetic core N.

In detail, as can be clearly seen in FIG. 2, each winding V is provided with an input end IN and with an output end OUT opposite each other with respect to the winding portion P.

Specifically, the input ends IN are connectable to the three phases and the neutral of the three-phase AC power supply line and the output ends OUT are connectable to the power unit.

It should be specified that in known filtering circuits C provided with multiple filters F, the connection between the filters themselves is made directly on the printed circuit board S by means of special connecting tracks side by side to each other or made in the inner layers with a conductive material (e.g., copper).

Specifically, the connecting tracks connect the input ends IN of one filter F to the power supply line, the output ends OUT of another filter to the power unit and the remaining input ends IN and output ends OUT to each other to define a plurality of intermediate connections between the various filters F.

So, one filter F is directly connected at input to the power supply line, another filter F is directly connected at output to the power unit and all filters F are connected in series to each other.

However, installing the filters F directly on the printed circuit board S and making the connections by means of connecting tracks turns out to be a technical expedient that is not without its problems.

In this regard, it is worth thinking about the fact that the width with which the connecting tracks are made must necessarily be proportionate to the current values flowing through them to ensure that the same do not run the risk of overheating or even breaking down.

With this in mind, it is easy to appreciate how the aforementioned high currents impose, therefore, the need to build inconveniently wide connecting tracks. The greater width of tracks evidently results in a greater amount of conductive material to be used, and thus ends up negatively affecting the manufacturing costs of the filtering circuit C.

Not only that, but the fact that the connecting tracks made of conductive material are side by side or overlapping onto various layers causes a considerable heat exchange to be created between them, which considerably increases the temperature thereof.

This negative effect forces, among other things, even more material to be used to make the connecting tracks and ultimately ends up exacerbating the aforementioned problems related to the manufacturing costs of known filtering circuits C.

Not the least problem, having to employ connecting tracks of a certain size also ends up adversely affecting the final size of the filter itself, resulting in inconvenient issues related to the overall dimensions of the latter.

### DESCRIPTION OF THE INVENTION

The main aim of the present invention is to devise a filtering circuit for battery chargers of electric or hybrid vehicles which allows reducing the use of materials for the manufacture thereof and, therefore, lowering the manufacturing costs compared with known filtering circuits.

Another object of the present invention is to devise a filtering circuit for battery chargers of electric or hybrid vehicles which allows increasing thermal dissipation compared to the prior art mentioned above.

Another object of the present invention is to devise a filtering circuit for battery chargers of electric or hybrid vehicles which allows the aforementioned drawbacks of the prior art to be overcome within the framework of a simple, rational, easy and effective to use as well as cost-effective solution.

The aforementioned objects are achieved by this filtering circuit for battery chargers of electric or hybrid vehicles having the characteristics of claim 1.

### BRIEF DESCRIPTION OF THE DRAWINGS

Other characteristics and advantages of the present invention will become more apparent from the description of a preferred, but not exclusive, embodiment of a filtering circuit for battery chargers of electric or hybrid vehicles, illustrated by way of an indicative, yet non-limiting example, in the accompanying tables of drawings in which:

FIG. 1 is an axonometric, overall view of a filtering circuit of known type;

FIG. 2 is a schematic view from above of the known circuit from FIG. 1;

FIG. 3 is an axonometric, overall view of the filtering circuit according to the invention;

FIG. 4 is an axonometric view of a detail of the filtering circuit according to the invention;

FIG. 5 shows a schematic view from below of the circuit from FIG. 4;

FIG. 6 is an axonometric view of a detail from FIG. 5;

FIG. 7 shows a section, carried out along the sectional plane VII-VII, from FIG. 6.

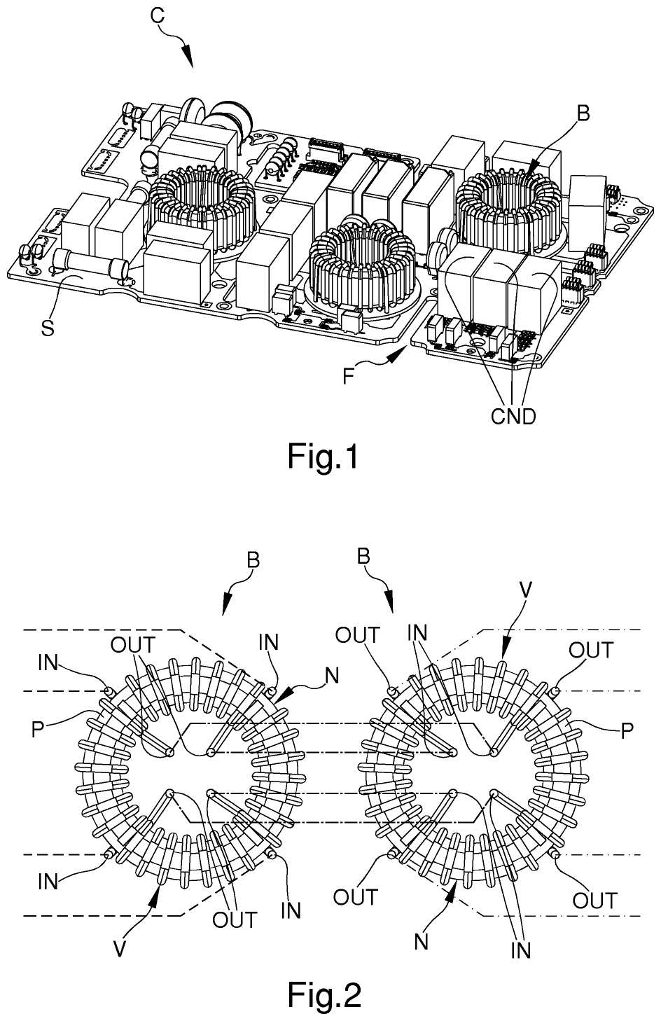

### EMBODIMENTS OF THE INVENTION

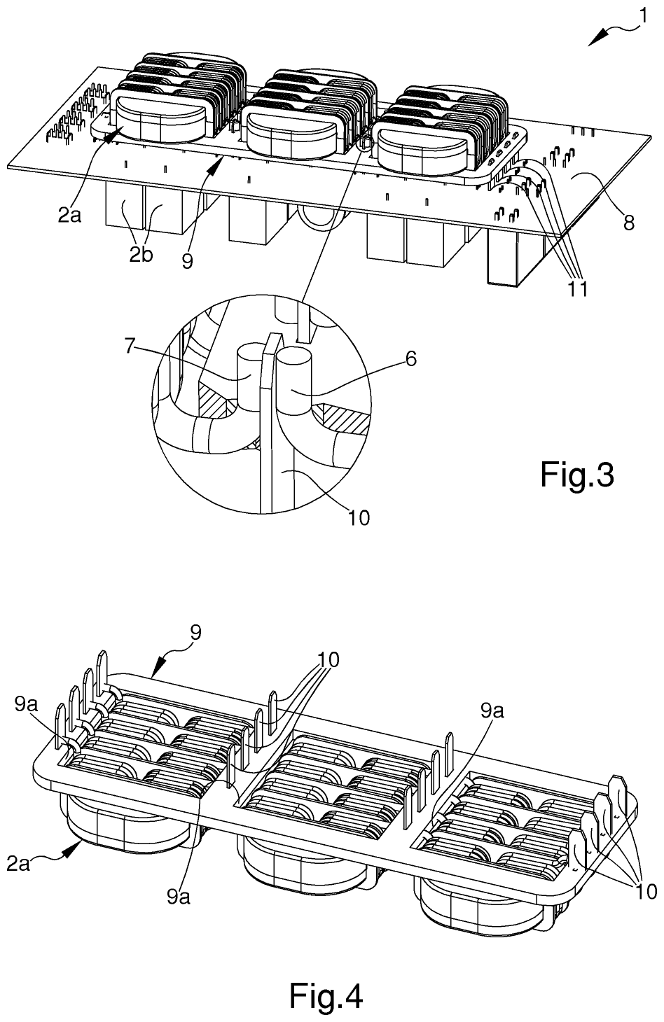

With particular reference to FIGS. 3 through 7, reference numeral 1 globally denotes a filtering circuit for battery chargers of electric or hybrid vehicles. The filtering circuit 1 for battery chargers of electric or hybrid vehicles can be installed in at least one battery charger of electric or hybrid vehicles, provided with at least one power unit for converting alternating current into predefined direct current.

Specifically, the circuit 1 comprises a plurality of filters 2a, 2b for electromagnetic disturbances connected in series to each other and provided with at least one coil 2a comprising:
at least one ferromagnetic core 3;
at least one winding 4a, 4b which is wound on a respective winding portion 5a, 5b of the ferromagnetic core 3 and is provided with at least one input end 6 connectable to at least one AC power supply line and with at least one output end 7 connectable to the power unit.

In this regard, it is possible to provide a circuit 1 which can be connected to a single-phase alternating current power supply line and, therefore, provided with a coil 2a having a single winding 4a, 4b.

Alternatively, the circuit 1 may be connected to a three-phase alternating current power supply line.

In this case, as shown in FIGS. 3 to 5, the coil 2a comprises four windings 4a, 4b.

Specifically, each of the windings 4a, 4b is wound around a respective winding portion 5a, 5b of the ferromagnetic core 3 and is provided with a respective input end 6 connectable to one of the three phases or to the neutral of at least one three-phase alternating current power supply line, and with a respective output end 7 connectable to the power unit.

In actual facts, referring to a configuration of use of the circuit 1 wherein it is installed on a battery charger and is connected to the power supply line and to the power unit, each three of the four input ends 6 are connected to one of the three phases, while the fourth input end 6 is connected to the neutral.

By explaining the ferromagnetic core 3 in detail, it should first be said that it is preferably made of a ferromagnetic metal (e.g., iron) or ferromagnetic compounds marked by low coercivity and low hysteresis.

In particular, the ferromagnetic core 3 is made of at least one amorphous or nanocrystalline alloy.

Such alloys do, in fact, offer excellent performance (e.g., saturation induction greater than 0.9 T, high relative magnetic permeability and excellent stability under varying temperature) for working frequencies on the order of a few tens of kHz and for applications under critical environmental conditions.

Specifically, the choice of an amorphous ferromagnetic core 3 is particularly suitable in the case of manufacturing a filter 2a, 2b of extremely compact size and traversed by high direct currents with small high-frequency components.

In fact, in this case, the saturation induction level of the ferromagnetic core 3 enables the same to control high currents effectively, limiting the losses thereof in the face of their low ripple.

What's more, a ferromagnetic core 3 made of nanocrystalline alloy features decidedly low losses not only for limited current ripples but also for considerable variations in the magnetic field, making it suitable for the construction of switching transformers.

Ultimately, making the ferromagnetic core 3 from amorphous or nanocrystalline alloy allows, for the same size and number of turns, much higher inductances to be achieved than using materials such as ferrite, thus enabling the filter 2, 8 to perform its function in a particularly efficient manner.

In terms of conformation, as clearly visible in FIG. 7, the ferromagnetic core 3 in accordance with the preferred embodiment comprises:
at least a first stretch 3a, substantially rectilinear in shape;
at least a second stretch 3b, substantially rectilinear in shape and arranged substantially parallel side by side to the first stretch 3a;
at least two connecting stretches 3c, substantially curvilinear in shape and positioned between the first stretch 3a and the second stretch 3b to connect the latter to each other so as to make a closed ferromagnetic core 3.

Specifically, the first stretch 3a and the second stretch 3b have substantially coincident lengths.

Again, the connecting stretches 3c are substantially shaped as a D.

In actual facts, the ferromagnetic core 3 is substantially oval-shaped.

However, different conformations of the ferromagnetic core 3, e.g. substantially toroidal, cannot be ruled out.

In this case, the winding portions 5a, 5b have a substantially curved conformation and the windings 4a, 4b are wound on the winding portions themselves in a curvilinear manner.

Again, the ferromagnetic core 3 is made in a single body piece.

In other words, the first stretch 3a, the second stretch 3b and the connecting stretches 3c are connected to each other continuously and without the interposition of any welding joints.

It should, in this regard, be borne in mind that it is precisely the special oval shape of the ferromagnetic core 3 that allows the latter to be made as a single body piece and, therefore, to disregard the use of welding joints to connect the aforementioned stretches 3a, 3b, 3c.

This fact makes it possible to dramatically increase the magnetic properties (e.g., inductance) of the ferromagnetic core 3, consequently leading to even more effective control of the currents.

Going into more detail about the single coil 2a, it should first be specified that each of the windings 4a, 4b with which it is provided comprises a first plurality of turns 4a which is provided with the input end 6 and is wound around a respective first winding portion 5a of the ferromagnetic core 3.

Specifically, the turns belonging to the first plurality of turns 4a are all side by side to each other and are aligned with each other along at least a first axis of winding A1.

Similarly, the windings 4a, 4b also comprise a second plurality of turns 4b, connected to the first plurality of turns 4a, which is provided with the output end 7 and is wound around a respective second winding portion 5b of the ferromagnetic core 3 substantially opposite the first winding portion 5a.

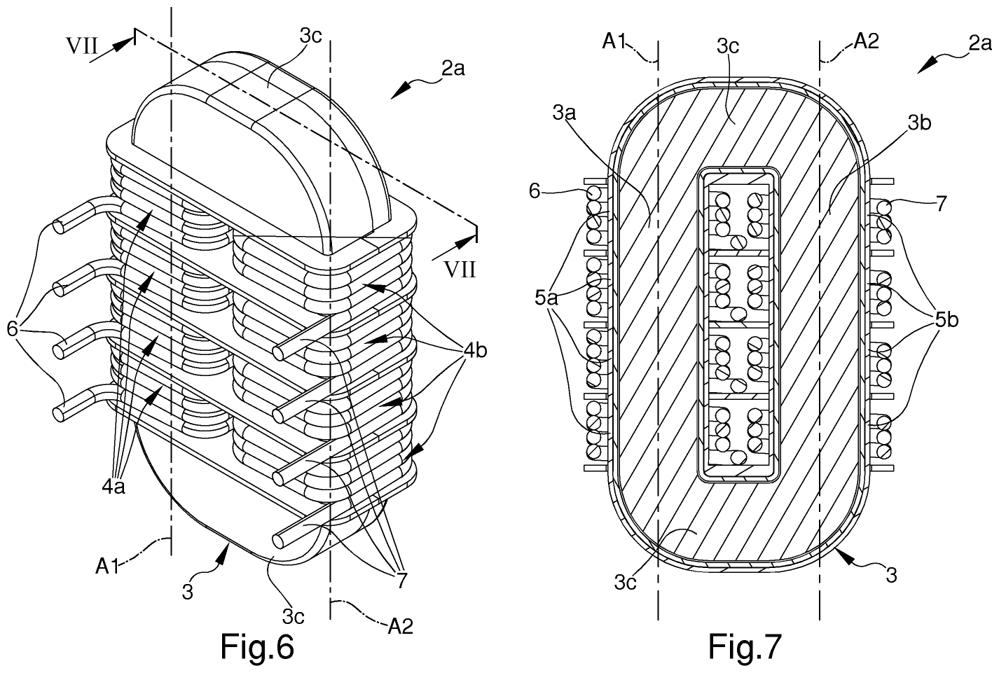

In particular, the turns belonging to the second plurality of turns 4b are all side by side to each other and are aligned with each other along at least a second axis of winding A2 parallel to and separate from the first axis of winding A1 (see FIG. 6 and FIG. 7 in this regard).

Specifically, the first pluralities of turns 4a of the windings 4a, 4b are wound on the first stretch 3a and the second pluralities of turns 4b of the windings 4a, 4b are wound on the second stretch 3b.

In this regard, referring to the preferred embodiment, to state that the first winding portions 5a, 5b and the second winding portions 5a, 5b are opposite each other is to mean that they are arranged on two straight, separate and mutually parallel stretches of the ferromagnetic core 3.

In other words, to state this is to say that the first axis of winding A1 and the second axis of winding A2 lie on the first stretch 3a and on the second stretch 3b respectively, and are parallel to the latter.

As can be seen in FIG. 4, the input end 6 and the output end 7 of each of the windings 4a, 4b are substantially aligned with each other on the first stretch 3a and on the second stretch 3b, respectively.

As will be clearer in the remainder of this disclosure, this fact proves to be particularly advantageous in that it allows the heat dissipation present in the circuit 1 to be increased, thus improving the thermal control of the latter. Conveniently, the first pluralities of turns 4a are wound around the first winding portions 5a, 5b with at least a first direction of winding and the second pluralities of turns 4b are wound around the second winding portions 5a, 5b with at least a second direction of winding opposite the first winding direction.

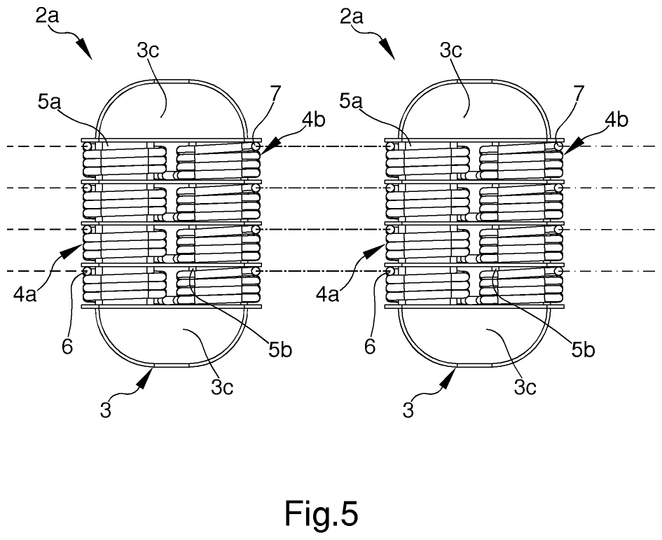

As is clearly visible in FIGS. 5 to 7, the first direction of winding is clockwise and the second direction of winding is counterclockwise.

The opposite case cannot however be ruled out wherein the first direction of winding is counterclockwise and the second direction of winding is clockwise.

In this regard, it should be pointed out that the direction of winding of the turns causes the orientation of the electric current flowing through them and, consequently, the direction of the magnetic field generated by it.

With this in mind, it is, therefore, easy to appreciate that the special expedient of winding the first plurality of turns 4a and the second plurality of turns 4b with opposite directions of winding makes it possible to generate magnetic fields having equal directions to each other and, therefore, to sum their respective inductances, thus increasing the filtering effectiveness of the circuit 1.

The filter 2a, 2b comprises, in addition, a plurality of line capacitors 2b, each connected to at least one of either the input ends 6 or the output ends 7.

Specifically, the line capacitors 2b are arranged between each phase and the neutral or between two phases.

Bearing in mind what has been described so far, it is easy to appreciate how, in actual facts, the filter 2a, 2b is of the type of an EMI filter.

According to the invention, the circuit 1 comprises at least one printed circuit board 8 adapted to support and connect the capacitors 2b to each other.

In this regard, the printed circuit board 8 comprises a plurality of connecting tracks, not shown in the figures for simplicity sake, made of a conductive material and adapted to electrically connect the capacitors 2b to each other.

In other words, the capacitors 2b are mounted on the printed circuit board 8 and are electrically connected to each other on the printed circuit board itself by means of the connecting tracks.

In accordance with the preferred embodiment, the circuit 1 comprises at least one supporting body 9 on which the coils 2a are mounted, which is associated with the printed circuit board 8.

Conveniently, the supporting body 9 comprises a plurality of housings 9a obtained passing through, where each of the housings 9a is adapted to house at least one respective coil 2a within it.

Specifically, the number of housings 9a is equal to the number of coils 2a.

Specifically, as visible in FIG. 4, the housings 9a have a substantially rectangular conformation.

The housings 9a are positioned side by side on the supporting body 9, so their number determines the length (i.e., the dimension defining the longitudinal development) of the supporting body itself.

To electrically connect the coils 2a to the printed circuit board 8, the circuit 1 according to the invention comprises a plurality of connecting elements 10 which are associated with each input end 6 and with each output end 7.

In particular, the supporting body 9 is provided with the connecting elements 10.

In accordance with the preferred embodiment, the connecting elements 10 are of the pin type.

Thus, in this case, the printed circuit board 8 is provided with a plurality of sockets 11 (as known in the technical jargon) into which the connecting elements 10 are fitted.

In actual facts, the connecting elements 10 and the sockets 11 make, when inserted into each other, a coupling by shape which allows the printed circuit board 8 and the supporting body 9 to be electrically connected.

It is important to add, at this point, that each of the output ends 7 of each coil 2a, except for the last one, is directly connected to a respective input end 6 of the next coil 2a and is associated together with the respective input end 6 to the same connecting element 10.

In actual facts, this means that each of the output ends 7 of each coil 2a, except for the last one, and each respective input end 6 of the next coil 2a share the same connecting element 10.

In this regard, therefore, to state that an output end 7 is directly connected to a respective input end 6 is to mean that they are associated with the same connecting element 10.

More precisely, as schematically shown in FIG. 5, the output ends 7 of each coil 2a and the respective input ends 6 of the next coil 2a connected to the same connecting element 10 define intermediate connections between two adjacent coils 2a which are parallel to each other.

Conveniently, the connecting elements 10 are arranged along a plurality of parallel rows of connecting elements 10 on the supporting body 9.

Specifically, each coil 2a on the supporting body 9 is positioned between two rows of connecting elements 10.

From this it follows that the connecting elements 10 are arranged in a number of rows equal to the number of coils 2a plus one, and that each row of connecting elements 10 is provided with four connecting elements 10.

It is important, at this point, to highlight that the expedients of providing a printed circuit board 8 onto which only capacitors 2b are mounted and of connecting coils 2a in series to the connecting elements 10 by means of their respective output ends 7 and of their respective input ends 6 make it possible to greatly reduce the amount of conductive material used in the construction of the circuit 1.

In fact, in this case, the electric current flows mainly through the coils 2a and only a small amount thereof in the capacitors 2b on the printed circuit board 8.

So, the connecting tracks made of conductive material become necessary, in this case, only to connect the capacitors 2b with each other and not, therefore, the coils 2a.

Since they do not, therefore, have to be traversed by high currents, the connecting tracks may be advantageously sized with smaller widths than the prior art; it is clear how this fact has a somewhat positive influence on material procurement costs, consequently lowering the manufacturing expenses for the circuit 1 as well as its size.

It is also worth highlighting that this same connection configuration causes the circuit 1 to effectively dissipate the heat generated by the flow of electric current, thus contributing, among other things, in reducing the amount of conductive material required for its making.

In this regard, the fact that the input ends 6 and the output ends 7 are substantially aligned contributes greatly to the thermal control of the circuit 1 since it allows the connections defined by the aforementioned ends to be kept suitably spaced from each other.

In accordance with the preferred embodiment shown in the figures, the circuit 1 comprises three filters 2a, 2b connected in series, where:
the input ends 6 of the first filter 2a, 2b are directly connected to the power supply line;
the output ends 7 of the third filter 2a, 2b are directly connected to the power unit;
the output ends 7 of the first and of the second filter 2a, 2b are directly connected to the input ends 6 of the second and of the third filter 2a, 2b, respectively.

It is specified, in this regard, that by using the term “directly” in reference to the connection between the input ends 6 and the power supply line, one wishes to mean that no additional magnetic component (such as, e.g., an additional coil 2a) is interposed between these two.

Similar considerations may apply when employing the aforementioned term in reference to the connection between the output ends 7 and the power unit.

Thus, the circuit 1 in accordance with the preferred embodiment defines four input connections to the power supply line, four output connections to the power unit and eight intermediate connections between the various filters 2a, 2b in series (i.e., four between the first and the second filter 2a, 2b and another four between the second and the third filter 2a, 2b).

This means, therefore, that the supporting body 9 is, in this case, provided with sixteen connecting elements 10 arranged along four rows of four connecting elements 10 each.

It cannot however be ruled out that the circuit may be provided with a different number of filters 2a, 2b, e.g., two filters 2a, 2b connected in series, or a different and, for example, larger number of filters 2a, 2b.

It has in practice been ascertained that the described invention achieves the intended objects.

In particular, the fact is emphasized that the special expedients of providing a printed circuit board on which only the capacitors are mounted and of directly connecting the coils to each other by means of their respective output and input ends makes it possible to greatly reduce the amount of conductive material used.

In fact, the connecting tracks made of conductive material become, in this case, only necessary to connect capacitors to each other, and for this reason they can be sized with smaller widths than the prior art, positively affecting material procurement and manufacturing costs.

Finally, it is highlighted that this same connecting configuration also makes it possible for the circuit to efficiently dissipate the heat generated by the flow of electric current; this contributes, among other things, in further reducing the amount of conductive material needed to make the circuit itself.

1. Filtering circuit (1) for battery chargers of electric or hybrid vehicles, which can be installed in at least one battery charger of electric or hybrid vehicles, provided with at least one power unit for converting alternating current into predefined direct current, comprising:
a plurality of filters (2a, 2b) for electromagnetic disturbances connected in series to each other and provided with:
at least one coil (2a) comprising:
at least one ferromagnetic core (3);
at least one winding (4a, 4b) which is wound on a respective winding portion (5a, 5b) of said ferromagnetic core (3) and is provided with at least one input end (6) connectable to at least one alternating current power supply line, and with at least one output end (7) connectable to said power unit;
a plurality of line capacitors (2b), each connected to at least one of either said input ends (6) or said output ends (7);
characterized by the fact that:
it comprises at least one printed circuit board (8) adapted to support and connect said capacitors (2b) to each other;
it comprises a plurality of connecting elements (10) which are associated with each of said input ends (6) and of said output ends (7) and are adapted to electrically connect said coils (2a) to said printed circuit board (8);
each of said output ends (7) of each said coil (2a), except for the last one, is directly connected to a respective said input end (6) of said next coil (2a) and is associated together with said respective input end (6) to a same said connecting element (10).

2. Circuit (1) according to claim 1, characterized by the fact that it comprises at least one supporting body (9) on which said coils (2a) are mounted, which is associated with said printed circuit board (8) and is provided with said connecting elements (10).

3. Circuit (1) according to claim 2, characterized by the fact that said connecting elements (10) are of the pin type, said printed circuit board (8) being provided with a plurality of sockets (11) into which said connecting elements (10) are fitted.

4. Circuit (1) according to claim 1, characterized by the fact that said coil (2a) comprises four of said windings (4a, 4b), wherein each of said windings (4a, 4b) is wound around a respective said winding portion (5a, 5b) of said ferromagnetic core (3) and is provided with a respective said input end (6) connectable to one of the three phases or to the neutral of at least one three-phase alternating current supply line, and with a respective said output end (7) connectable to said power unit.

5. Circuit (1) according to claim 1, characterized by the fact that it comprises three of said filters (2a, 2b) connected in series, wherein:
said input ends (6) of the first of said filters (2a, 2b) are directly connected to said power supply line;
said output ends (7) of the third of said filters (2a, 2b) are directly connected to said power unit;
said output ends (7) of the first and of the second of said filters (2a, 2b) are directly connected to said input ends (6) of the second and of the third of said filters (2a, 2b), respectively.

6. Circuit (1) according to claim 1, characterized by the fact that each of said windings (4a, 4b) comprises:
a first plurality of turns (4a) which is provided with said input end (6) and is wound around a respective first winding portion (5a) of said ferromagnetic core (3); and
a second plurality of turns (4b), connected to said first plurality of turns (4a), which is provided with said output end (7) and is wound around a respective second winding portion (5b) of said ferromagnetic core (3) opposite said first winding portion (5a).

7. Circuit (1) according to claim 6, characterized by the fact that said ferromagnetic core (3) comprises:
at least a first stretch (3a), substantially rectilinear in shape, on which are wound said first plurality of turns (4a) of said windings (4a, 4b);
at least a second stretch (3b), substantially rectilinear in shape and arranged substantially parallel side by side to said first stretch (3a), on which are wound said second plurality of turns (4b) of said windings (4a, 4b);
at least two connecting stretches (3c), substantially curvilinear in shape and positioned between said first stretch (3a) and said second stretch (3b) to connect the latter to each other.

8. Circuit (1) according to claim 7, characterized by the fact that said input end (6) and said output end (7) of each of said windings (4a, 4b) are substantially aligned with each other on said first stretch (3a) and on said second stretch (3b), respectively.
